(19) United States
(12) Patent Application Publication
(10) Pub. No.: US 2023/0361759 A1
(43) Pub. Date: Nov. 9, 2023

(54) ELECTRONIC DEVICE

(71) Applicant: Innolux Corporation, Miaoli County (TW)

(72) Inventors: Sheng-Feng Huang, Miaoli County (TW); Kung-Chen Kuo, Miaoli County (TW); Yi-Hung Lin, Miaoli County (TW)

(73) Assignee: Innolux Corporation, Miaoli County (TW)

(21) Appl. No.: 18/296,381

(22) Filed: Apr. 6, 2023

Related U.S. Application Data
(60) Provisional application No. 63/337,612, filed on May 3, 2022.

(30) Foreign Application Priority Data
Jan. 31, 2023 (CN) 202310048480.8

(51) Int. Cl. H03K 3/01; H03K 19/20

(52) U.S. Cl. CPC H03K 3/01; H03K 19/20

(57) ABSTRACT

An electronic device is provided. The electronic device includes a first unit and a second unit. The first unit includes a first driving circuit and a first inverter. The second unit is adjacent to the first unit. The second unit includes a second driving circuit. The first inverter is electrically connected to the first driving circuit and the second driving circuit.

### CROSS-REFERENCE TO RELATED APPLICATION

This application claims the priority benefit of U.S. provisional application Ser. No. 63/337,612, filed on May 3, 2022 and Chinese application no. 202310048480.8, filed on Jan. 31, 2023. The entirety of each of the above-mentioned patent applications is hereby incorporated by reference herein and made a part of this specification.

### BACKGROUND

### Technical Field

The disclosure relates to an electronic device, and particularly relates to an electronic device including inverters.

### Description of Related Art

An electronic device may use an inverter circuit to invert a received signal to generate an inverted signal, and operates based on the inverted signal. In some aspects, the electronic device includes a unit array. The unit array includes a plurality of units. In order for the plurality of units to operate based on the inverted signal, the inverter circuit needs to have a larger layout area, and thus is disposed outside a range of the unit array (for example, in a peripheral region). The inverter circuit generates the inverted signal outside the unit array and provides the inverted signal to the plurality of units.

However, when the inverted signal is transmitted from the outside of the unit array to the unit array, it may attenuate due to a resistance-capacitance (RC) load in the unit array. Therefore, how to reduce the attenuation of the inverted signal is one of the research focuses of those skilled in the art.

### SUMMARY

The disclosure is directed to an electronic device.

The disclosure provides an electronic device including a first unit and a second unit. The first unit includes a first driving circuit and a first inverter. The second unit is adjacent to the first unit. The second unit includes a second driving circuit. The first inverter is electrically connected to the first driving circuit and the second driving circuit.

The disclosure provides an electronic device including a plurality of scan lines and a first unit. The plurality of scan lines includes a first scan line. The first unit includes a first driving circuit and a first inverter. The first inverter is electrically connected to the first driving circuit and the first scan line.

Based on the above description, the inverter is disposed in the first unit. In this way, the inverted signal received by the first unit does not have obvious attenuation. In addition, the inverter is designed to correspond to the first unit or to correspond to the first unit and the second unit. The layout area of the inverter may be reduced. In this way, the layout area of the first unit will not increase significantly.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic diagram of an electronic device according to a first embodiment of the disclosure.

FIG. 2 is a schematic diagram of an electronic device according to a second embodiment of the disclosure.

FIG. 3 is a schematic diagram of an electronic device according to a third embodiment of the disclosure.

FIG. 4 is a schematic diagram of an electronic device according to a fourth embodiment of the disclosure.

FIG. 5 is a layout diagram of an electronic device according to an embodiment of the disclosure.

FIG. 6 is a schematic diagram of an electronic device according to a fifth embodiment of the disclosure.

FIG. 7 is a schematic diagram of an electronic device according to a sixth embodiment of the disclosure.

FIG. 8 is a schematic diagram of an electronic device according to a seventh embodiment of the disclosure.

FIG. 9 is a schematic diagram of an electronic device according to an eighth embodiment of the disclosure.

FIG. 10 is a schematic circuit diagram of an electronic device according to an embodiment of the disclosure.

FIG. 11 is a schematic circuit diagram of an electronic device according to another embodiment of the disclosure.

### DESCRIPTION OF THE EMBODIMENTS

The disclosure may be understood from the following detailed description made with reference to the drawings as described below. It should be noted that, for purposes of clarity and easy understanding by readers, each drawing of the disclosure depicts a part of an electronic device, and some components in each drawing may not be drawn to scale. In addition, the number and size of each device depicted in the drawings are illustrative only and not intended to limit the scope of the disclosure.

Certain terms are used throughout the description and the following claims to refer to specific components. As will be understood by those skilled in the art, manufacturers of electronic equipment may refer to components by different names. This specification does not intend to distinguish between components that differ in name but not function. In the following description and in the claims, the terms “comprising”, “including” and “having” are used in an open manner and should therefore be construed as meaning “including but not limited to . . . ” Therefore, when the terms “comprising”, “including”, and/or “having” are used in the description of the disclosure, they specify existence of corresponding features, regions, steps, operations, and/or components, but do not exclude existence of one or more corresponding features, regions, steps, operations, and/or components.

It should be understood that when a component is referred to as being “coupled to”, “connected to” or “conducted to” another component, the component may be directly connected to the other component and may directly establish an electrical connection, or there may be intermediate components there between for relaying electrical connection (indirect electrical connection). In contrast, when a component is referred to as being “directly coupled to,” “directly connected to,” or “directly connected to” another component, there are no intervening components present.

Although terms such as first, second, third, etc., may be used to describe various constituent components, such constituent components are not limited by these terms. The terms are used only to distinguish a constituent component from other constituent components in the specification. The claims may not use the same terms, but may use the terms first, second, third etc., with respect to a required order of the components. Therefore, in the following description, a first constituent component may be a second constituent component in the claims.

The electronic device of the disclosure may include a display device, an antenna device, a sensing device, a light-emitting device, a tiled device, a touch display, a curved device or a free shape device, but the disclosure is not limited thereto. The electronic device may include a bendable or flexible electronic device. The electronic device may, for example, include liquid crystal, light-emitting diodes, quantum dots (QDs), fluorescence, phosphor, other suitable display media, or a combination of the above materials, but the disclosure is not limited thereto. The light-emitting diodes may, for example, include organic light-emitting diodes (OLEDs), mini LEDs, micro LEDs or quantum dot LEDs (which may include QLED, QDLED), or other suitable materials, or a combination of the above materials, but the disclosure is not limited thereto. The display device may include, for example, a tiled display device, but the disclosure is not limited thereto. The antenna device may be, for example, a device with communication and/or electromagnetic wave modulation functions, such as a liquid crystal antenna, a Wifi router, a reconfigurable intelligent surface device, or a suitable combination of the above, but the disclosure is not limited thereto. The antenna device may include, for example, an antenna tiled device, but the disclosure is not limited thereto. It should be noted that the electronic device can be any permutation and combination of the aforementioned devices, but the disclosure is not limited thereto. In addition, a shape of the electronic device may be rectangular, circular, polygonal, a shape with curved edges, or other suitable shapes. The electronic device may have peripheral systems such as a driving system, a control system, a light source system, etc., to support a display device, an antenna device or a tiled device, but the disclosure is not limited thereto. The sensing device may include a camera, an infrared sensor (infrared sensor) or a fingerprint sensor, etc., and the present disclosure is not limited thereto. In some embodiments, the sensing device may further include a flashlight, an infrared (infrared, IR) light source, other sensors, electronic components, or a combination thereof, but is not limited thereto.

In the disclosure, the embodiments use “pixel unit” or “modulation unit” as a unit for describing a specific region including at least one functional circuit for at least one specific function. A region of a “pixel unit” or “modulation unit” depends on the unit used to provide a particular function, and adjacent units may share the same parts or wires, but may also comprise specific parts of themselves therein. For example, the adjacent units may share the same scan line or the same data line, but a unit may also have its own transistors or capacitors.

It should be noted that technical features in different embodiments described below may be replaced, reorganized or mixed with each other to form another embodiment without departing from the spirit of the disclosure.

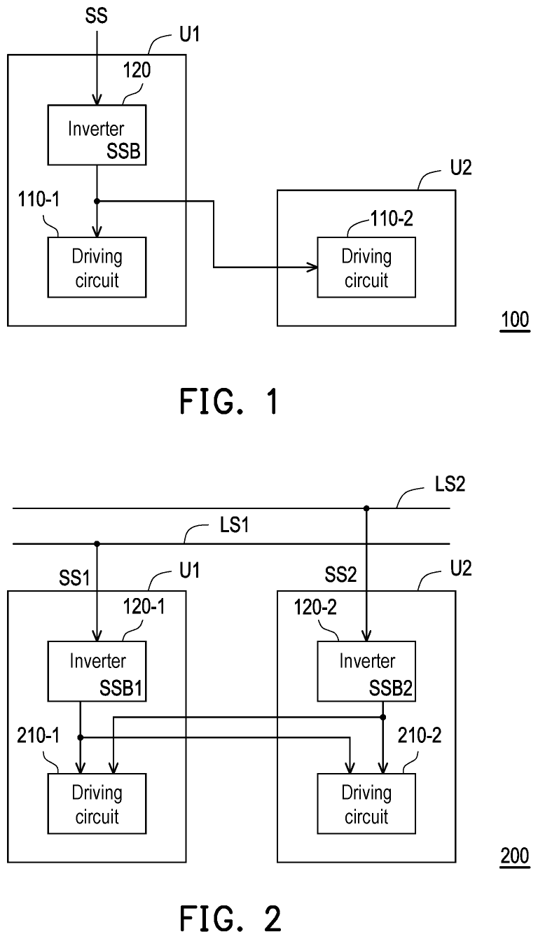

Referring to FIG. 1, FIG. 1 is a schematic diagram of an electronic device according to a first embodiment of the disclosure. In the embodiment, an electronic device 100 includes a unit U1 and a unit U2. The unit U2 is adjacent to the unit U1. The unit U1 includes a driving circuit 110-1 and an inverter 120. The unit U2 includes a driving circuit 110-2. The inverter 120 is electrically connected to the driving circuit 110-1 and the driving circuit 110-2. In the embodiment, the inverter 120 receives a signal SS and inverts the signal SS to generate an inverted signal SSB. For example, the inverter 120 may perform conversion of a high voltage level and a low voltage level. The inverter 120 may convert the received high voltage level (the signal SS) to generate a low voltage level (the inverted signal SSB), and may also convert the received low voltage level (the signal SS) to generate a high voltage level (the inverted signal SSB). In the embodiment, the inverter 120 provides the inverted signal SSB to the driving circuit 110-1 in the unit U1. Therefore, the driving circuit 110-1 operates according to the inverted signal SSB. In addition, the inverter 120 provides the inverted signal SSB to the driving circuit 110-2 in the unit U2. Therefore, the driving circuit 110-2 operates according to the inverted signal SSB.

It should be noted that the inverter 120 is disposed in the unit U1. In this way, the inverted signal SSB received by the unit U1 does not have obvious attenuation. Furthermore, the inverter 120 is designed to correspond to the unit U1 or to correspond to the units U1, U2. A layout area of the inverter 120 may be reduced. In this way, a layout area of the unit U1 will not increase significantly.

For the ease of description, in the embodiment, the units U1 and U2 are taken as an example for descriptions. The number of the unit U1 disclosed in the disclosure may be one or more, which is not limited by the embodiment.

Referring to FIG. 2, FIG. 2 is a schematic diagram of an electronic device according to a second embodiment of the disclosure. In the embodiment, an electronic device 200 includes scan lines LS1, LS2 and a unit U1 (the disclosure is not limited to the number of the scan lines). The unit U1 is electrically connected to the scan line LS1. The unit U1 includes a driving circuit 210-1 and an inverter 120-1. The inverter 120-1 is electrically connected to the driving circuit 210-1 and the scan line LS1. In the embodiment, the inverter 120-1 receives a signal SS1 and inverts the signal SS1 to generate an inverted signal SSB1. The inverter 120-1 provides the inverted signal SSB1 to the driving circuit 210-1.

In the embodiment, the electronic device 200 further includes a unit U2. The unit U2 is adjacent to the unit U1. The unit U2 is electrically connected to the scan line LS2. The unit U2 includes a driving circuit 210-2 and an inverter 120-2. The inverter 120-2 is electrically connected to the driving circuit 210-2. In the embodiment, the inverter 120-2 receives a signal SS2 and inverts the signal SS2 to generate an inverted signal SSB2. The inverter 120-2 provides the inverted signal SSB2 to the driving circuit 210-2.

In addition, the inverter 120-1 is further electrically connected to the driving circuit 210-2. The inverter 120-2 is further electrically connected to the driving circuit 210-1. Therefore, the driving circuit 210-1 receives the inverted signals SSB1, SSB2. The drive circuit 210-2 also receives the inverted signals SSB1, SSB2.

Based on actual design requirements, in some embodiments, the driving circuit 210-1 may be designed to be electrically connected to the inverter 120-1 alone. In some embodiments, the driving circuit 210-2 may be designed to be electrically connected to the inverter 120-2 alone.

The signal SS1 is different from the signal SS2. For example, the signal SS1 and the signal SS2 are different scan signals with different timings. For example, the driving circuit 210-1 uses the inverted signal SSB1 to end a pre-charging operation or perform a voltage compensation operation. The driving circuit 210-1 uses the inverted signal SSB2 to perform a reset operation or a discharge operation. The disclosure is not limited to the application of the inverted signals SSB1 and SSB2. For another example, the driving circuit 210-2 uses the inverted signal SSB1 to perform a pre-charging operation. The driving circuit 210-2 uses the inverted signal SSB2 to end the pre-charging operation or perform a voltage compensation operation.

The electronic device 200 further includes the unit U2. The inverter 120-1 of the unit U1 is further electrically connected to the scan line LS1. In addition, the inverter 120-2 of the unit U2 is further electrically connected to the scan line LS2. The inverter 120-1 receives the signal SS1 through the scan line LS1. The inverter 120-2 receives the signal SS2 through the scan line LS2.

It should be noted that the driving circuit 210-1 and the driving circuit 210-2 respectively need the inverted signals SSB1 and SSB2 to operate. The inverters 120-1 and 120-2 used for generating the inverted signals SSB1 and SSB2 are respectively disposed in the different units U1 and U2. In other words, in the embodiment, the units U1 and U2 each need to accommodate a single inverter. In this way, a layout area of the units U1 and U2 will not increase significantly.

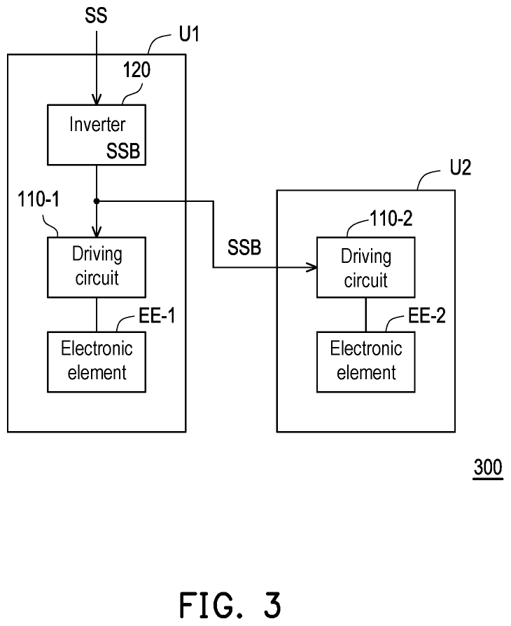

Referring to FIG. 3, FIG. 3 is a schematic diagram of an electronic device according to a third embodiment of the disclosure. In the embodiment, an electronic device 300 includes a unit U1 and a unit U2. The unit U1 includes a driving circuit 110-1, an inverter 120, and an electronic element EE-1. The unit U2 is adjacent to the unit U1. The unit U2 includes a driving circuit 110-2 and an electronic element EE-2. The electronic element EE-1 is electrically connected to the driving circuit 110-1. The electronic element EE-2 is electrically connected to the driving circuit 110-2. In the embodiment, the inverter 120 receives a signal SS and inverts the signal SS to generate an inverted signal SSB. The inverter 120 provides the inverted signal SSB to the driving circuit 110-1 and the driving circuit 110-2. Therefore, the driving circuit 110-1 drives the electronic element EE-1 according to the inverted signal SSB. The driving circuit 110-2 drives the electronic element EE-2 according to the inverted signal SSB.

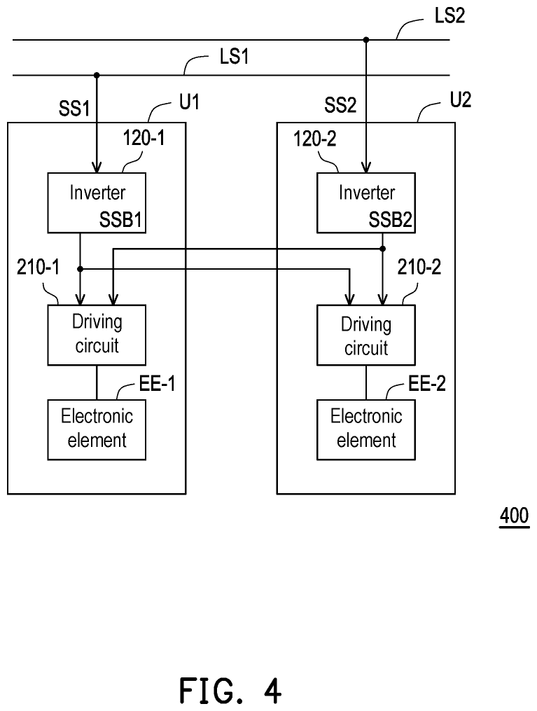

Referring to FIG. 4, FIG. 4 is a schematic diagram of an electronic device according to a fourth embodiment of the disclosure. In the embodiment, the electronic device 200 includes scan lines LS1, LS2 and a unit U1 (the number of scan lines is not limited by the disclosure). The unit U1 is electrically connected to the scan line LS1. The unit U1 includes a driving circuit 210-1, an inverter 120-1, and an electronic element EE-1. The inverter 120-1 is electrically connected to the driving circuit 210-1 and the scan line LS1. The electronic element EE-1 is electrically connected to the driving circuit 210-1. In the embodiment, the inverter 120-1 receives a signal SS1 and inverts the signal SS1 to generate an inverted signal SSB1. The inverter 120-1 provides the inverted signal SSB1 to the driving circuit 210-1.

In the embodiment, the electronic device 200 further includes a unit U2. The unit U2 is adjacent to unit U1. The unit U2 is electrically connected to the scan line LS2. The unit U2 includes a driving circuit 210-2, an inverter 120-2, and an electronic element EE-2. The electronic element EE-2 is electrically connected to the driving circuit 210-2. The inverter 120-2 is electrically connected to the driving circuit 210-2 and the scan line LS2. In the embodiment, the inverter 120-2 receives a signal SS2 and inverts the signal SS2 to generate an inverted signal SSB2. The inverter 120-2 provides the inverted signal SSB2 to the driving circuit 210-2.

In addition, the inverter 120-2 is also electrically connected to the driving circuit 210-1. The driving circuit 210-1 receives the inverted signals SSB1, SSB2. Therefore, the driving circuit 210-1 drives the electronic element EE-1 according to the inverted signals SSB1 and SSB2. The inverter 120-1 is also electrically connected to the driving circuit 210-2. The drive circuit 210-2 also receives the inverted signals SSB1, SSB2. Therefore, the driving circuit 210-2 drives the electronic element EE-2 according to the inverted signals SSB1 and SSB2.

Based on actual design requirements, in some embodiments, the driving circuit 210-1 may be designed to be electrically connected to the inverter 120-1 alone. Therefore, the driving circuit 210-1 drives the electronic element EE-1 according to the inverted signal SSB1. In some embodiments, the driving circuit 210-2 may be designed to be electrically connected to the inverter 120-2 alone. Therefore, the driving circuit 210-2 drives the electronic element EE-2 according to the inverted signal SSB2.

For example, the signal SS1 and the signal SS2 are respectively different scan signals with different timings. An electronic device 400 further includes scan lines LS1, LS2. The inverter 120-1 of the unit U1 is also electrically connected to the scan line LS1. In addition, the inverter 120-2 of the unit U2 is also electrically connected to the scan line LS2.

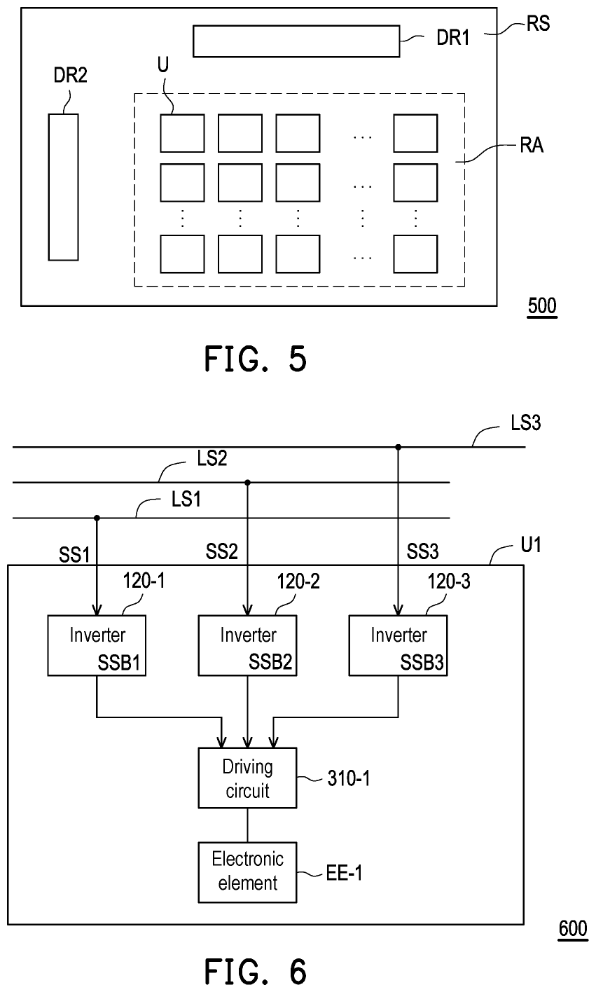

Referring to FIG. 4 and FIG. 5 at the same time, FIG. 5 is a layout diagram of an electronic device according to an embodiment of the disclosure. In the embodiment, an electronic device 500 includes a peripheral region RS, an active region RA (or referred to as a non-peripheral region), and a plurality of units U. The peripheral region RS is adjacent to or surrounds the active region RA. In the embodiment, the units U are all set in the active region RA. Any two adjacent units U in the active region RA may be implemented by the units U1 and U2 in FIG. 1 to FIG. 4. Therefore, it should be understood that the above-mentioned inverters are disposed in the active region RA.

In the embodiment, the electronic device 500 further includes a first circuit DR1 and a second circuit DR2. Both of the first circuit DR1 and the second circuit DR2 are disposed in the peripheral region RS. For example, the first circuit DR1 is, for example, a data driving circuit. The second circuit DR2 is, for example, a gate drive circuit. The second circuit DR2, for example, provides scan signals to the units U through a plurality of scan lines (for example, the scan lines LS1, LS2).

Referring to FIG. 6, FIG. 6 is a schematic diagram of an electronic device according to a fifth embodiment of the disclosure. In the embodiment, an electronic device 600 includes a unit U1. The unit U1 includes a driving circuit 310-1, inverters 120-1, 120-2, 120-3, an electronic element EE-1, and scan lines LS1, LS2, LS3. In the embodiment, the inverter 120-1 receives a signal SS1 through the scan line LS1, and inverts the signal SS1 to generate an inverted signal SSB1. The inverter 120-1 provides the inverted signal SSB1 to the driving circuit 310-1. The inverter 120-2 receives a signal SS2 through the scan line LS2, and inverts the signal SS2 to generate an inverted signal SSB2. The inverter 120-2 provides the inverted signal SSB2 to the driving circuit 310-1. The inverter 120-3 receives a signal SS3 through the scan line LS3, and inverts the signal SS3 to generate an inverted signal SSB3. The inverter 120-3 provides the inverted signal SSB3 to the driving circuit 310-1. The driving circuit 310-1 drives the electronic element EE-1 according to the inverted signals SSB1, SSB2, and SSB3. In some embodiment, the scan line LS1 is adjacent to the scan line LS2, but the disclosure is not limited thereto. In some embodiment, the scan line LS2 is adjacent to the scan line LS3, but the disclosure is not limited thereto.

In the embodiment, the signals SS1, SS2, and SS3 are respectively different scan signals with different timings. For example, the driving circuit 310-1 uses the inverted signal SSB1 to perform a pre-charging operation. The driving circuit 310-1 uses the inverted signal SSB2 to end the pre-charging operation or to perform a voltage compensation operation. The driving circuit 310-1 uses the inverted signal SSB3 to perform a reset operation or a discharge operation. The present disclosure does not limit the applications of the inverted signals SSB1, SSB2, SSB3.

In the embodiment, the situation that the unit U1 includes three inverters 120-1, 120-2, and 120-3 is taken as an example for description. However, the disclosure is not limited thereto. The unit U1 of the disclosure may include one or more inverters.

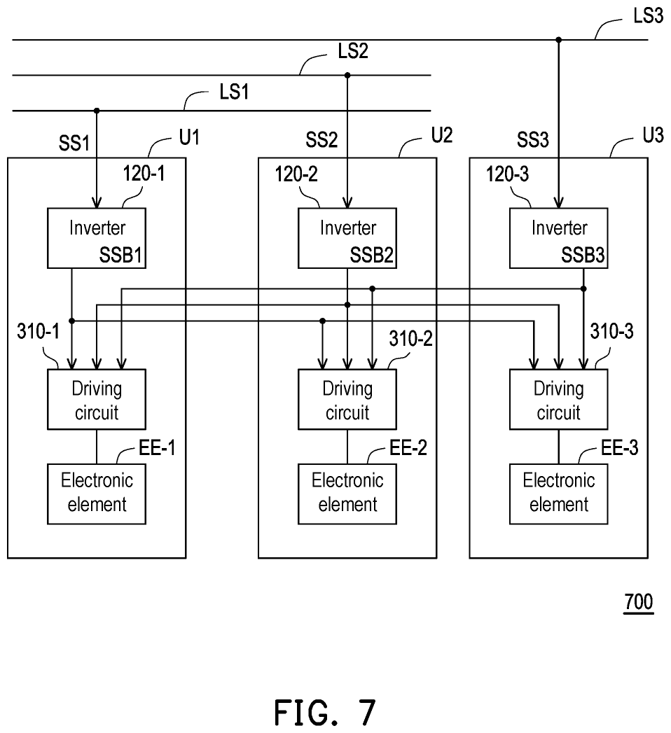

Referring to FIG. 7, FIG. 7 is a schematic diagram of an electronic device according to a sixth embodiment of the disclosure. In the embodiment, an electronic device 700 includes units U1, U2, and U3. The unit U1 includes a driving circuit 310-1, an inverter 120-1, and an electronic element EE-1. The unit U2 includes a driving circuit 310-2, an inverter 120-2, and an electronic element EE-2. The unit U3 includes a driving circuit 310-3, an inverter 120-3, and an electronic element EE-3. In the embodiment, the inverter 120-1 receives a signal SS1 and inverts the signal SS1 to generate an inverted signal SSB1. The inverter 120-1 provides the inverted signal SSB1 to the driving circuits 310-1, 310-2, 310-3. The inverter 120-2 receives a signal SS2 and inverts the signal SS2 to generate an inverted signal SSB2. The inverter 120-2 provides the inverted signal SSB2 to the driving circuits 310-1, 310-2, 310-3. The inverter 120-3 receives a signal SS3 and inverts the signal SS3 to generate an inverted signal SSB3. The inverter 120-3 provides the inverted signal SSB3 to the driving circuits 310-1, 310-2, 310-3.

Therefore, the driving circuit 310-1 drives the electronic element EE-1 according to the inverted signals SSB1, SSB2, and SSB3. The driving circuit 310-2 drives the electronic element EE-2 according to the inverted signals SSB1, SSB2, and SSB3. The driving circuit 310-3 drives the electronic element EE-3 according to the inverted signals SSB1, SSB2, and SSB3.

It should be noted that the driving circuits 310-1, 310-2, 310-3 respectively need the inverted signals SSB1, SSB2, SSB3 to operate. The inverters 120-1, 120-2, 120-3 used for generating the inverted signals SSB1, SSB2, SSB3 are respectively disposed in different units U1, U2, U3. In other words, in the embodiment, the units U1, U2, and U3 each need to accommodate a single inverter. In this way, the layout area of the units U1, U2, and U3 will not increase significantly.

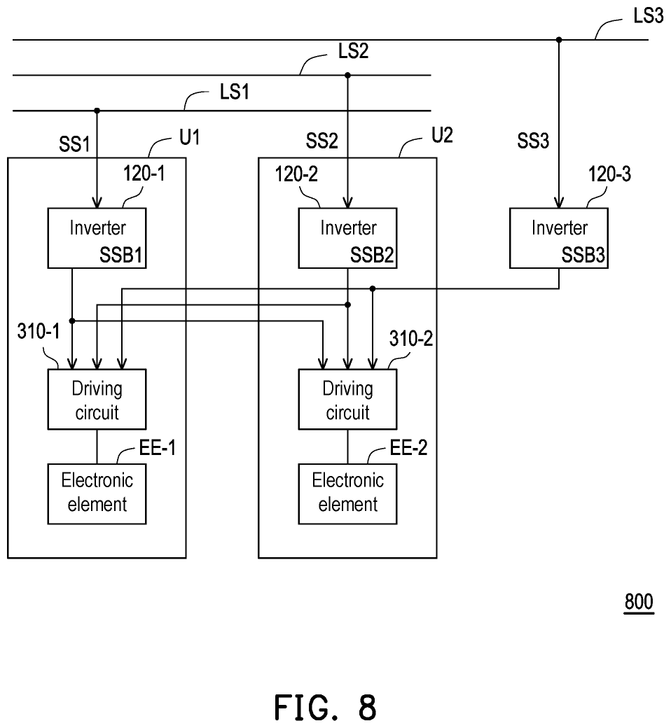

Referring to FIG. 8, FIG. 8 is a schematic diagram of an electronic device according to a seventh embodiment of the disclosure. In the embodiment, an electronic device 800 includes a unit U1, a unit U2 and an inverter 120-3. The unit U1 and the unit U2 are disposed in the active region RA, and the inverter 120-3 is disposed in the peripheral region RS. The unit U1 includes a driving circuit 310-1, an inverter 120-1, and an electronic element EE-1. The unit U2 includes a driving circuit 310-2, an inverter 120-2, and an electronic element EE-2. In the embodiment, the inverter 120-1 receives a signal SS1 and inverts the signal SS1 to generate an inverted signal SSB1. The inverter 120-1 provides the inverted signal SSB1 to the driving circuit 310-1 and the driving circuit 310-2. The inverter 120-2 receives a signal SS2 and inverts the signal SS2 to generate an inverted signal SSB2. The inverter 120-2 provides the inverted signal SSB2 to the driving circuit 310-1 and the driving circuit 310-2. The inverter 120-3 receives a signal SS3 and inverts the signal SS3 to generate an inverted signal SSB3. The inverter 120-3 provides the inverted signal SSB3 to the driving circuit 310-1 and the driving circuit 310-2.

Therefore, the driving circuit 310-1 drives the electronic element EE-1 according to the inverted signals SSB1, SSB2, and SSB3. The driving circuit 310-2 drives the electronic element EE-2 according to the inverted signals SSB1, SSB2, and SSB3.

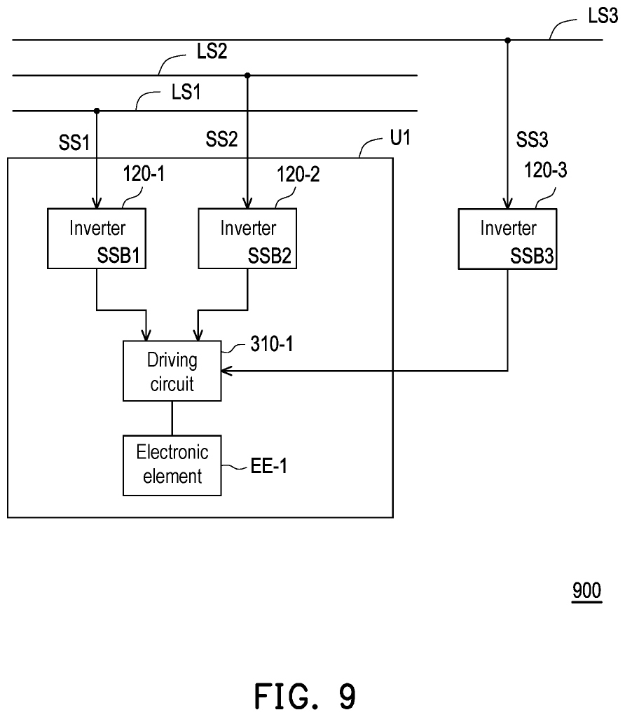

Referring to FIG. 9, FIG. 9 is a schematic diagram of an electronic device according to an eighth embodiment of the disclosure. In the embodiment, an electronic device 900 includes a unit U1 and an inverter 120-3. The unit U1 is disposed in the active region RA, and the inverter 120-3 is disposed in the peripheral region RS. The unit U1 includes a driving circuit 310-1, inverters 120-1, 120-2, and an electronic element EE-1. In the embodiment, the inverter 120-1 receives a signal SS1 and inverts the signal SS1 to generate an inverted signal SSB1. The inverter 120-1 provides the inverted signal SSB1 to the driving circuit 310-1. The inverter 120-2 receives a signal SS2 and inverts the signal SS2 to generate an inverted signal SSB2. The inverter 120-2 provides the inverted signal SSB2 to the driving circuit 310-1. The inverter 120-3 receives a signal SS3 and inverts the signal SS3 to generate an inverted signal SSB3. The inverter 120-3 provides the inverted signal SSB3 to the driving circuit 310-1. The driving circuit 310-1 drives the electronic element EE-1 according to the inverted signals SSB1, SSB2, and SSB3.

In the embodiment, the situation that the unit U1 includes two inverters 120-1 and 120-2 is taken as an example for description. However, the disclosure is not limited thereto. The unit U1 of the disclosure may include one or more inverters.

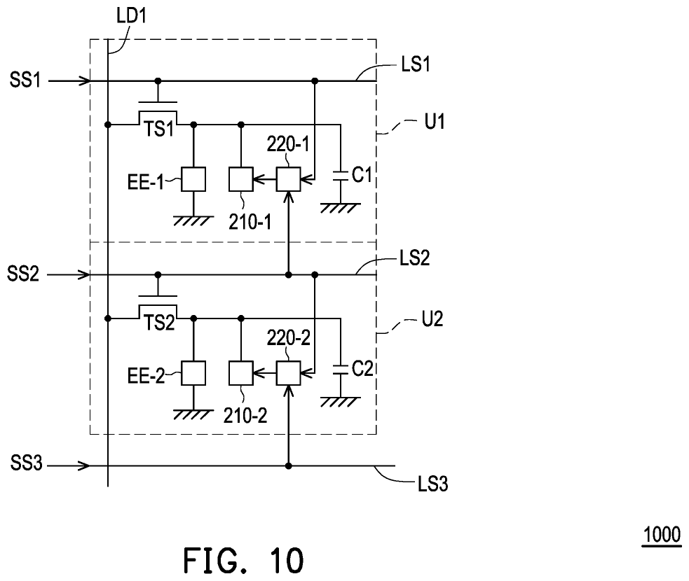

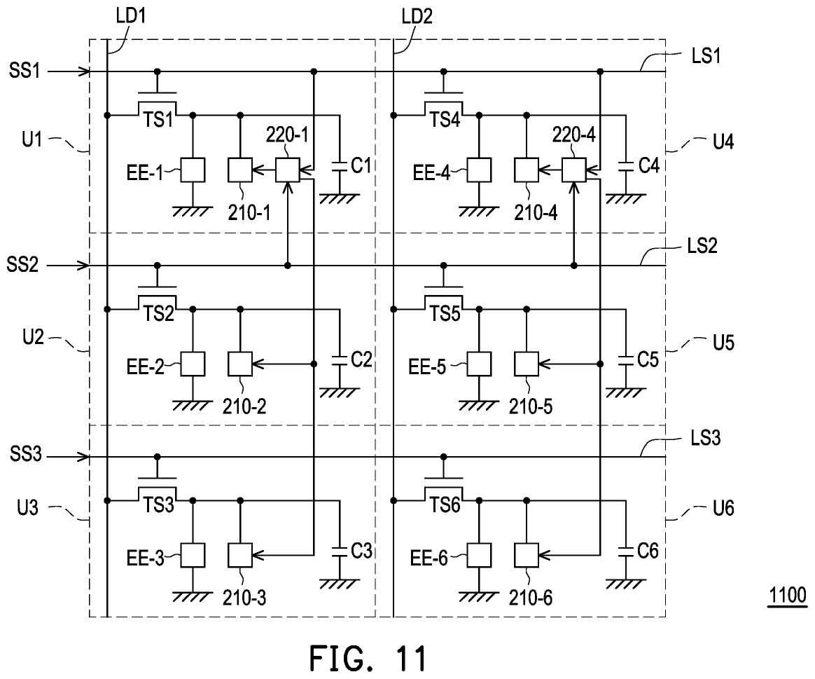

Referring to FIG. 10. FIG. 10 is a schematic circuit diagram of an electronic device according to an embodiment of the disclosure. In the embodiment, an electronic device 1000 includes units U1, U2, a data line LD1, and scan lines LS1, LS2, LS3. The unit U1 includes a switch transistor TS1, a driving circuit 210-1, an inverter 220-1, an electronic element EE-1, and a capacitor C1. A first terminal of the switch transistor TS1 is electrically connected to the data line LD1. A control terminal of the switch transistor TS1 is electrically connected to the scan line LS1. The electronic element EE-1 is electrically connected between a second terminal of the switch transistor TS1 and a reference voltage. The reference voltage may be a reference low voltage (for example, grounding) or a common voltage. The driving circuit 210-1 is, for example, electrically connected to the electronic element EE-1 through the second terminal of the switch transistor TS1. The capacitor C1 is electrically connected between the second terminal of the switch transistor TS1 and the reference voltage. The inverter 220-1 is electrically connected to the scan lines LS1, LS2 and the driving circuit 210-1. The inverter 220-1 receives a signal SS1 through the scan line LS1, and inverts the signal SS1 to generate a first inverted signal (for example, the inverted signal SSB1). The inverter 220-1 receives a signal SS2 through the scan line LS2, and inverts the signal SS2 to generate a second inverted signal (for example, the inverted signal SSB2). The inverter 220-1 provides the first inverted signal and the second inverted signal to the driving circuit 210-1. Therefore, the driving circuit 110-1 drives the electronic element EE-1 according to the first inverted signal and the second inverted signal.

The unit U2 includes a switch transistor TS2, a driving circuit 210-2, an inverter 220-2, an electronic element EE-2, and a capacitor C2. A first terminal of the switch transistor TS2 is electrically connected to the data line LD1. A control terminal of the switch transistor TS2 is electrically connected to the scan line LS2. The electronic element EE-2 is electrically connected between the second terminal of the switch transistor TS2 and the reference voltage. The driving circuit 210-2 is, for example, electrically connected to the electronic element EE-2 through the second terminal of the switch transistor TS2. The capacitor C2 is electrically connected between the second terminal of the switch transistor TS2 and the reference voltage. The inverter 220-2 is electrically connected to the scan lines LS2, LS3 and the driving circuit 210-2. The inverter 220-2 receives a signal SS2 through the scan line LS2, and inverts the signal SS2 to generate a second inverted signal (for example, the inverted signal SSB2). The inverter 220-2 receives a signal SS3 through the scan line LS3, and inverts the signal SS3 to generate a third inverted signal (for example, the inverted signal SSB3). The inverter 220-2 provides the second inverted signal and the third inverted signal to the driving circuit 210-2. Therefore, the driving circuit 210-1 drives the electronic element EE-2 according to the second inverted signal and the third inverted signal. In the embodiment, the scan line LS1 is adjacent to the scan line LS2, but the disclosure is not limited thereto. In the embodiment, the scan line LS2 is adjacent to the scan line LS3, but the disclosure is not limited thereto.

In the embodiment, the inverter 220-1 may be an inverter circuit including the inverters 120-1 and 120-2 as shown in FIGS. 2, 4, 6-9. The inverter 220-2 may be an inverter circuit including the inverters 120-2 and 120-3 as shown in FIGS. 6-9.

In some embodiments, the capacitors C1 and C2 may be omitted.

Referring to FIG. 11, FIG. 11 is a schematic circuit diagram of an electronic device according to another embodiment of the disclosure. In the embodiment, an electronic device 1100 includes units U1-U6, data lines LD1, LD2, and scan lines LS1, LS2, LS3. The scan line L2 may be adjacent to the scan line L1 and the scan line L3. The data line LD1 may be adjacent to the data line LD2. The unit U1 includes a switch transistor TS1, a driving circuit 210-1, an inverter 220-1, an electronic element EE-1, and a capacitor C1. The unit U2 includes a switch transistor TS2, a driving circuit 210-2, an electronic element EE-2, and a capacitor C2. The unit U3 includes a switch transistor TS3, a driving circuit 210-3, an electronic element EE-3, and a capacitor C3. The unit U4 includes a switch transistor TS4, a driving circuit 210-4, an inverter 220-4, an electronic element EE-4, and a capacitor C4. The unit U5 includes a switch transistor TS5, a driving circuit 210-5, an electronic element EE-5, and a capacitor C5. The unit U6 includes a switch transistor TS6, a driving circuit 210-6, an electronic element EE-6, and a capacitor C6. In the embodiment, a circuit configuration of the unit U1 is similar to the circuit configuration of the unit U1 in FIG. 10, so that detail thereof is not repeated here.

In the embodiment, the inverter 220-1 receives a signal SS1 through the scan line LS1, and inverts the signal SS1 to generate a first inverted signal (for example, the inverted signal SSB1). The inverter 220-1 receives a signal SS2 through the scan line LS2, and inverts the signal SS2 to generate a second inverted signal (for example, the inverted signal SSB2). The inverter 220-1 provides the first inverted signal and the second inverted signal to the driving circuit 210-1. Therefore, the driving circuit 210-1 drives the electronic element EE-1 according to the first inverted signal and the second inverted signal.

In the unit U2, a first terminal of the switch transistor TS2 is electrically connected to the data line LD1. A control terminal of the switch transistor TS2 is electrically connected to the scan line LS2. The electronic element EE-2 is electrically connected between the second terminal of the switch transistor TS2 and the reference voltage. The driving circuit 210-2 is electrically connected to the inverter 220-1. The driving circuit 210-2 is, for example, electrically connected to the electronic element EE-2 through the second terminal of the switch transistor TS2. The capacitor C2 is electrically connected between the second terminal of the switch transistor TS2 and the reference voltage.

In the unit U3, a first terminal of the switch transistor TS3 is electrically connected to the data line LD1. A control terminal of the switch transistor TS3 is electrically connected to the scan line LS3. The electronic element EE-3 is electrically connected between the second terminal of the switch transistor TS3 and the reference voltage. The driving circuit 210-3 is electrically connected to the inverter 220-1. The driving circuit 210-3 is, for example, electrically connected to the electronic element EE-3 through the second terminal of the switch transistor TS3. The capacitor C3 is electrically connected between the second terminal of the switch transistor TS3 and the reference voltage.

In the embodiment, the inverter 220-1 provides the first inverted signal and the second inverted signal to the driving circuits 210-2, 210-3. Therefore, the driving circuit 210-2 drives the electronic element EE-2 according to the first inverted signal and the second inverted signal. The driving circuit 210-3 drives the electronic element EE-3 according to the first inverted signal and the second inverted signal.

In the unit U4, a first terminal of the switch transistor TS4 is electrically connected to the data line LD2. A control terminal of the switch transistor TS4 is electrically connected to the scan line LS1. The electronic element EE-4 is electrically connected between the second terminal of the switch transistor TS4 and the reference voltage. The driving circuit 210-4 is, for example, electrically connected to the electronic element EE-4 through the second terminal of the switch transistor TS4. The capacitor C4 is electrically connected between the second terminal of the switch transistor TS4 and the reference voltage. The inverter 220-4 is electrically connected to the scan lines LS1, LS2 and the driving circuit 210-4. The inverter 220-4 receives a signal SS1 through the scan line LS1, and inverts the signal SS1 to generate a first inverted signal (for example, the inverted signal SSB1). The inverter 220-4 receives a signal SS2 through the scan line LS2, and inverts the signal SS2 to generate a second inverted signal (for example, the inverted signal SSB2). The inverter 220-4 provides the first inverted signal and the second inverted signal to the driving circuit 210-4. Therefore, the driving circuit 210-4 drives the electronic element EE-4 according to the first inverted signal and the second inverted signal.

In the embodiment, the inverter 220-4 receives the signal SS1 through the scan line LS1, and inverts the signal SS1 to generate the first inverted signal. The inverter 220-4 receives the signal SS2 through the scan line LS2, and inverts the signal SS2 to generate the second inverted signal. The inverter 220-4 provides the first inverted signal and the second inverted signal to the driving circuit 210-4. Therefore, the driving circuit 210-4 drives the electronic element EE-4 according to the first inverted signal and the second inverted signal.

In the unit U5, a first terminal of the switch transistor TS5 is electrically connected to the data line LD2. A control terminal of the switch transistor TS5 is electrically connected to the scan line LS2. The electronic element EE-5 is electrically connected between the second terminal of the switch transistor TS5 and the reference voltage. The driving circuit 210-5 is electrically connected to the inverter 220-4. The driving circuit 210-5 is, for example, electrically connected to the electronic element EE-5 through the second terminal of the switch transistor TS5. The capacitor C5 is electrically connected between the second terminal of the switch transistor TS5 and the reference voltage.

In the unit U6, a first terminal of the switch transistor TS6 is electrically connected to the data line LD2. A control terminal of the switch transistor TS6 is electrically connected to the scan line LS3. The electronic element EE-6 is electrically connected between the second terminal of the switch transistor TS6 and the reference voltage. The driving circuit 210-6 is electrically connected to the inverter 220-4. The driving circuit 210-6 is, for example, electrically connected to the electronic element EE-6 through the second terminal of the switch transistor TS6. The capacitor C6 is electrically connected between the second terminal of the switch transistor TS6 and the reference voltage.

In the embodiment, the inverter 220-4 provides the first inverted signal and the second inverted signal to the driving circuits 210-5, 210-6. Therefore, the driving circuit 210-5 drives the electronic element EE-5 according to the first inverted signal and the second inverted signal. The driving circuit 210-6 drives the electronic element EE-6 according to the first inverted signal and the second inverted signal.

In the disclosure, the schematic diagrams (i.e., FIGS. 1-4, 6-9) of the electronic devices may be, for example, schematic diagrams of display devices and antenna devices, and a layout diagram (i.e., FIG. 5) of the electronic device may be, for example, a layout diagram of a display device and an antenna device. The schematic circuit diagrams (i.e., FIGS. 10-11) of the electronic devices may be, for example, schematic circuit diagrams of display devices and antenna devices (the disclosure is not limited thereto).

For example, when the electronic device is a display device, the units U1 and U2 are each a pixel unit. The electronic elements EE-1 and EE-2 are each a light-emitting element or a liquid crystal element, but the disclosure is not limited thereto. The signal SS may be at least one of a scan signal, a data signal, a lighting control signal and a reset signal, but the disclosure is not limited thereto.

In some embodiments, the electronic device is an antenna device, therefore, the units U1 and U2 are each a modulation unit. The electronic elements EE-1 and EE-2 are each a modulating element, such as a varactor, but the disclosure is not limited thereto. In addition, when the electronic device is an antenna device, it may have a function of modulating electromagnetic waves. For example, the electronic elements EE-1 and EE-2 may modulate a frequency, phase, amplitude of electromagnetic waves, or a suitable combination thereof, but the disclosure is not limited thereto. The signal SS may be at least one of a scan signal and a data signal, but the disclosure is not limited thereto.

In summary, the first unit or a first modulation unit includes an inverter. The inverter inverts a signal to generate an inverted signal, and provides the inverted signal to the driving circuit of the first unit. In addition, in some embodiments, the inverter further provides the inverted signal to the driving circuits of other units. In the way, the inverted signal will not have obvious attenuation. In addition, the inverter is designed to correspond to the first unit or to correspond to the first unit and the second unit. The layout area of the inverter may be reduced. In this way, the layout area of the first unit will not increase significantly.

It will be apparent to those skilled in the art that various modifications and variations can be made to the disclosed embodiments without departing from the scope or spirit of the disclosure. In view of the foregoing, it is intended that the disclosure covers modifications and variations provided they fall within the scope of the following claims and their equivalents.

What is claimed is:

1. An electronic device, comprising:
a first unit, comprising a first driving circuit and a first inverter; and
a second unit, adjacent to the first unit, wherein the second unit comprises a second driving circuit,
wherein the first inverter is electrically connected to the first driving circuit and the second driving circuit.

2. The electronic device according to claim 1, wherein the second unit further comprises:
a second inverter, electrically connected to the first driving circuit and the second driving circuit.

3. The electronic device according to claim 2, further comprising:
a first scan line, wherein the first inverter is electrically connected to the first scan line.

4. The electronic device according to claim 3, wherein the first inverter receives a first signal through the first scan line, and inverts the first signal to generate a first inverted signal.

5. The electronic device according to claim 4, further comprising:
a second scan line, wherein the second inverter is electrically connected to the second scan line.

6. The electronic device according to claim 5, wherein the second inverter receives a second signal through the second scan line, and inverts the second signal to generate a second inverted signal.

7. The electronic device according to claim 6, wherein the first driving circuit receives at least one of the first inverted signal and the second inverted signal.

8. The electronic device according to claim 6, wherein the first unit further comprises:
a first electronic element, electrically connected to the first driving circuit,
wherein the first driving circuit drives the first electronic element according to at least one of the first inverted signal and the second inverted signal.

9. The electronic device according to claim 1, further comprising:
an active region, wherein the first unit and the second unit are disposed in the active region;
a peripheral region, adjacent to the active region; and
a third inverter, disposed in the peripheral region, and electrically connected to at least one of the first driving circuit and the second driving circuit.

10. The electronic device according to claim 1, wherein at least one of the first unit and the second unit further comprises:
a fourth inverter, electrically connected to the corresponding at least one of the first driving circuit and the second driving circuit.

11. An electronic device, comprising:
a plurality of scan lines, comprising a first scan line; and
a first unit, comprising:
a first driving circuit; and
a first inverter, electrically connected to the first driving circuit and the first scan line.

12. The electronic device according to claim 11, wherein the plurality of scan lines further comprise:
a second scan line, electrically connected to the first inverter.

13. The electronic device according to claim 11, wherein the first unit further comprises:
a first electronic element, electrically connected to the first driving circuit.

14. The electronic device according to claim 11, further comprising:
a second unit, adjacent to the first unit, wherein the second unit comprises a second driving circuit and a second inverter,
wherein the second inverter is electrically connected to the second driving circuit.

15. The electronic device according to claim 14, wherein the plurality of scan lines further comprise:
a second scan line, electrically connected to the second inverter.

16. The electronic device according to claim 15, wherein the plurality of scan lines further comprise:
a third scan line, electrically connected to the second inverter.

17. The electronic device according to claim 11, further comprising:
a second unit, adjacent to the first unit, wherein the second unit comprises a second driving circuit,
wherein the first inverter is further electrically connected to the second driving circuit.

18. The electronic device according to claim 17, wherein the second unit further comprises:
a second electronic element, electrically connected to the second driving circuit.

19. The electronic device according to claim 11, further comprising an active region, wherein the first unit is disposed in the active region;
a peripheral region, adjacent to the active region; and
a third inverter, disposed in the peripheral region and electrically connected to the first driving circuit.

20. The electronic device according to claim 11, wherein the first unit further comprises:
a fourth inverter, electrically connected to the first driving circuit.
